(19) United States
(12) Patent Application Publication
(10) Pub. No.: US 2009/0067256 A1
(43) Pub. Date: Mar. 12, 2009

(54) Thin gate stack structure for non-volatile memory cells and methods for forming the same

(75) Inventors: Arup Bhattacharyya, Essex Junction, VT (US); Garo Derderian, Manassas, VT (US)

Correspondence Address: DORSEY & WHITNEY LLP;INTELLECTUAL PROPERTY DEPARTMENT, SUITE 3400, 1420 FIFTH AVENUE, SEATTLE, WA, 98101, US

(73) Assignee: Micron Technology, Inc., Boise, ID (US)

(21) Appl. No.: 11/899,644

(22) Filed: Sep. 6, 2007

(51) Int. Cl. G11C 11/34; H01L 21/336; H01L 29/788

(52) U.S. Cl. 365/185.28; 257/321; 438/261; 257/E29.3; 257/E21.422

(57) ABSTRACT

Embodiments are described for reducing the programming voltage of a memory cell in a memory device. The memory cell includes a channel region extending between first and second diffusion regions formed in a substrate. A tunnel dielectric material is formed over the channel region. A storage medium is formed over the tunnel dielectric material to store electrical charge. The storage medium is disposed between a first interface material and a second interface material, each interface material provides a smoother interface between the storage medium and surrounding dielectric materials. A charge blocking material is formed over the storage medium, followed by a control gate material.

### TECHNICAL FIELD

Embodiments of the present invention relate generally to integrated memory devices, and more specifically to, in one or more embodiments, a thin gate stack structure for reducing programming voltages and improving voltage scalability of non-volatile memory devices.

### BACKGROUND

Flash memory, a type of non-volatile memory, includes an array of memory cells, with each memory cell comprising a floating gate field-effect transistor (FET) that is capable of holding an electric charge. A floating gate is formed between the control gate and the channel region of the FET transistor, and is electrically isolated in the memory cell by insulator layers of appropriate material and thickness surrounding the floating gate. Therefore, the floating gate is insulated from all other components of the non-volatile memory cell, and is thus “floating.” The memory cell array may be electrically programmed or erased by charging and discharging the floating gates of the memory cells. The data in a memory cell is determined by the presence or absence of the charge in the floating gate. Thus, memory cells can be programmed to store charge, erased by discharging the stored charge to allow another program operation, or the programmed data may be read from the memory cells. Charge is stored on the floating gate by applying appropriate voltages to the control gate, the drain region or the source region with reference to the substrate potential.

FIG. 1 is a cross-sectional view showing a prior art non-volatile memory cell 100 formed as a four terminal device having a control gate 12 and diffusion (source/drain) regions 11 with a semiconductor substrate 5, the fourth terminal, being at a reference potential. The semiconductor substrate 5 may be a silicon substrate or of some other semiconductor material that is doped to achieve desired transistor properties. The non-volatile memory cell 100 includes a gate stack having a floating gate 18 formed over the channel region 10 and/or portions of the source/drain regions 11. The gate stack typically includes successive layer of materials that includes a tunnel dielectric 20, the floating gate 18, a charge blocking dielectric layer 14 and the control gate 12. The floating gate 18 is conventionally formed of a conductive material such as doped polysilicon, and is electrically isolated between the tunnel dielectric layer 20 and the charge blocking dielectric layer 14 forming the charge storage plate of the stacked capacitor structure. If sufficient voltage is applied across the control gate 12, the channel region 10 below the gate stack will form a channel of carriers conducting current from its source to drain regions 11.

An electrical charge may be stored in the floating gate by a number of different charge injection mechanisms. For example, memory cells may be programmed and erased by channel hot-electron injection (CHE), where an appropriate high bias is applied to the control gate 12, and simultaneously another high bias is applied between the source and the drain, thereby creating a high electric potential across the control gate 12 and the channel region 10 to inject charge from the channel region 10 to the floating gate 18 across the tunnel dielectric layer 20. The bias applied to the control gate 12 relates to the amount of charge stored on the floating gate. The memory cell 100 may be similarly programmed and erased in a process called Fowler-Nordheim (FN) tunneling, where a field enhanced quantum mechanical tunneling of charges occurs through the conduction barrier or the valence barriers of the dielectric layers to place or remove charge to or from the floating gate 18.

The electrical structure formed between the floating gate 18, control gate 12 and channel region 10 in the memory cell 100 is equivalent to that of two series coupled capacitors, and therefore, the charge trapped on the floating gate 18 (by moving carriers through the insulation layers by CHE or FN tunneling) alters the effective threshold voltage of the memory cell 100. Changing the threshold voltage by trapping or removing charge from the floating gate 18 allows data values to be stored in the memory cell 100 and read by sensing the differing currents flowing across the channel region 10.

Conventional memory cells 100 utilize a thin layer of silicon oxide, SiO₂, (“oxide”) to form the tunnel dielectric layer 20 and a thicker layer of the oxide for the charge blocking dielectric layer 14 to isolate the floating gate 18 and to prevent charge flow to the gate. However, using oxide layers tend to result in a structure having high effective oxide thicknesses (EOT), which is a measure of the thickness of the various dielectric layers based on the capacitive characteristics of the gate stack. For example, the overall EOT (from the control gate 12 to the channel region 10) for conventional non-volatile memory cells typically ranges from 15 nm to 20 nm, due to the thickness requirement of the tunnel dielectric layer 20 to sustain standard retention parameters (data retention for 10 years and 10⁶ cycles). That is, the dielectric layers 14, 20 should have sufficient thickness and have high enough conduction bands to be effective as tunnel barriers and prevent leakage or back-tunneling of the trapped charges.

As a result of the relatively high EOT, a relatively high voltage is required for programming and erasing the memory cells using CHE, FN tunneling and other programming mechanisms. A resulting problem is that the high voltages required for the programming and erase operations can cause damage to the dielectric layers. High energy fields imposed on the gate insulator stack cause local weak spots, shallow traps and defects in the silicon-insulator interfaces, thus breaking stable bonds and eventually degrading the dielectric properties of the layers, causing enhanced stored charge leakage and reduced cell endurance. The high voltage requirement additionally creates problems with adjacent memory cells which must be sufficiently spaced apart so as not to be disturbed by parasitic capacitive coupling during programming operations. This problem limits feature size scaling capabilities, and affects the overall cell density. Another problem is that the high voltage requirement is generally much higher than the supply voltages provided to the devices (1.2 to 5V). The overall device size may be increased due to the components that are housed to internally generate the higher voltages, which can increase power consumption and impact the cost of fabrication.

FIG. 2 shows a prior art non-volatile memory cell 200 that illustrates another conventional charge blocking dielectric layer 22 that allows for the use of dielectric materials having a high K (i.e., a dielectric constant greater than the dielectric constant of silicon oxide, K≈3.9) to somewhat reduce the EOT of the gate stack while providing sufficient protection from back-tunneling of charge and charge loss to the control gate. A reduced EOT gate stack requires a smaller programming voltage. The charge blocking dielectric layer 22 is comprised of a stack of oxide-nitride-oxide (“ONO”) inter-poly dielectric material formed between the control gate 12 and the floating gate 18. However, despite the high K material in the ONO layer 22, the overall EOT (from the control gate 12 to the channel region 10) for the non-volatile memory cell 200 remains relatively high.

There is, therefore, a need, for example, for a gate stack structure for floating gate memory cells that can be used with a lower programming/erase voltage, without sacrificing data retention and cyclability.

### BRIEF DESCRIPTION OF THE DRAWINGS

FIG. 1 is a simplified cross-sectional view of a prior art semiconductor non-volatile memory cell having a floating gate.

FIG. 2 is a simplified cross-sectional view of a prior art semiconductor non-volatile memory cell having a floating gate and an oxide-nitride-oxide (ONO) charge blocking layer.

FIG. 3 is a simplified cross-sectional view of a semiconductor non-volatile memory cell that includes a floating gate according to an embodiment of the invention.

FIG. 4 is a simplified cross-sectional view of the semiconductor non-volatile memory cell of FIG. 2 having a high K charge blocking layer according to an embodiment of the invention.

FIG. 5 is a simplified cross-sectional view of a semiconductor non-volatile memory cell that includes a floating gate according to another embodiment of the invention.

FIGS. 6A and 6B are energy band diagrams illustrating a band-gap gate stack of the memory cell according to an embodiment of FIG. 5.

FIG. 7 is a simplified cross-sectional view of the semiconductor non-volatile memory cell of FIG. 5 that includes a high K charge blocking layer according to another embodiment of the invention.

FIG. 8 is a simplified cross-sectional view of a semiconductor non-volatile memory cell that includes a floating gate according to another embodiment of the invention.

FIG. 9 is a simplified cross-sectional view of a semiconductor non-volatile memory cell according to another embodiment of the invention.

FIG. 10 is an energy band diagram illustrating a band-gap gate stack of the memory cell according to FIG. 9.

FIG. 11 is a table illustrating gate stack options having varying effective oxide thicknesses according to one or more embodiments of the invention.

FIG. 12 is a block diagram showing a non-volatile memory device having non-volatile memory cells according to one or more embodiments of the invention.

FIG. 13 is a block diagram of a processor-based system that includes the non-volatile memory device of FIG. 7 according to one or more embodiments of the invention.

### DETAILED DESCRIPTION

Certain details are set forth below to provide a sufficient understanding of embodiments of the invention. However, it will be clear to one skilled in the art that embodiments of the invention may be practiced without these particular details. Moreover, the particular embodiments of the present invention described herein are provided by way of example and should not be used to limit the scope of the invention to these particular embodiments. In other instances, well-known circuits, control signals, and timing protocols have not been shown in detail in order to avoid unnecessarily obscuring the invention. Furthermore, it will be appreciated that the drawings shown in various Figures are not to scale, and are provided to further one's understanding of embodiments of the invention.

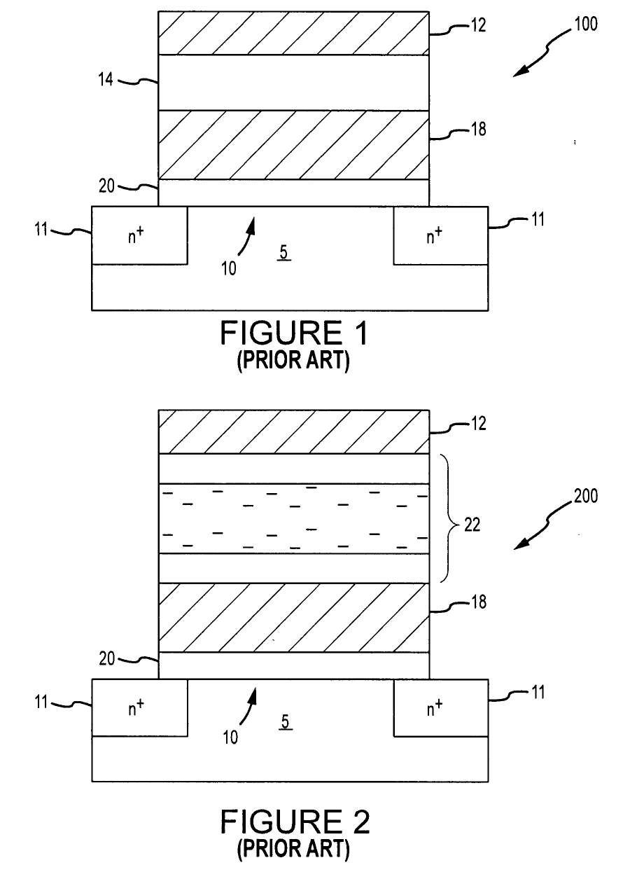

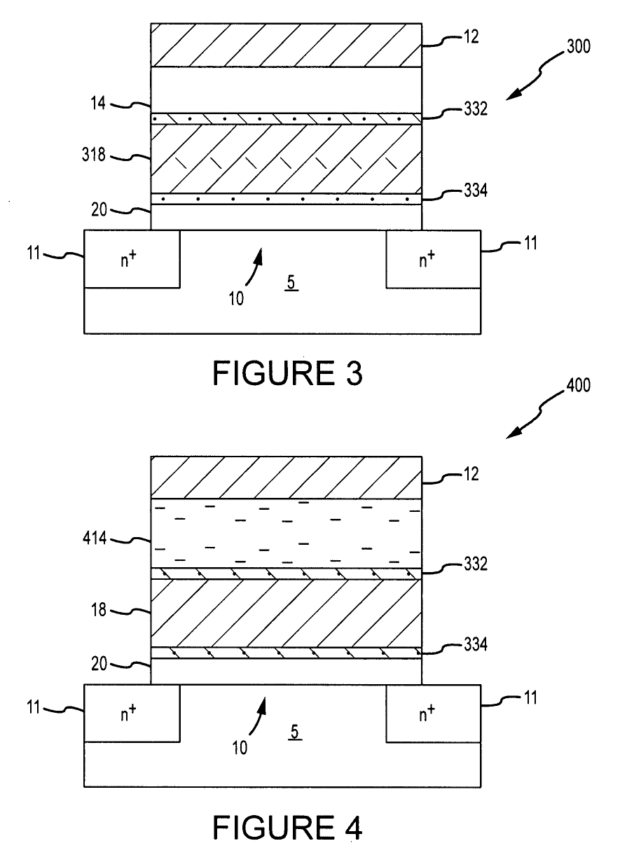

FIG. 3 shows a semiconductor memory cell 300 that includes a storage medium, such as a floating gate 318 modified to have a smoother interface with both the tunnel oxide 20 and the charge-blocking oxide layer 14. The memory cell 300, and subsequent memory cells to be described, includes many of the same elements as the memory cell 100 of FIG. 1. In the interest of brevity, these common elements have been provided with the same reference numbers, and will not be described again. Also, for illustration purposes, the memory cell 300 and subsequent memory cells are N⁺ doped source/drain regions in P⁻ doped substrate. Due to the polysilicon nature of the conventional floating gate 18 in FIG. 1, the interface with the tunnel oxide 20 and the oxide of the charge blocking layer 14 is rough with random orientations of grains. The “grainy” interface creates high local fields, particularly at high voltages, and enhances leakage paths for stored charges to leak out. Since the floating gate 318 is a conductive plate, charges will bleed out at an accelerated rate once a preferred leakage path is formed. The floating gate 318 may be modified by adding thin high K trapping layers 332, 334 of dielectric material at the top and bottom surfaces of the floating gate 318 to reduce the grainy interfaces associated with the neighboring layers of dielectric material. For example, the interfaces are smoothened between the polysilicon of the floating gate 318 and the oxide materials of the tunnel layer 20 and the charge blocking layer 14 by incorporating layers 332 and 334. Local high field effects are reduced by the trapping layers 332, 334, thereby reducing the formation of leakage paths and charge leakage, while simultaneously providing discrete high density of trapping sites at the interface for charges injected from the silicon substrate 10 during programming operations. The charges may be readily transported to the floating gate 318 by direct tunneling through the trapping layers 332, 334 and are trapped in the floating gate 318. By forming the trapping layers 332, 334 with high K dielectric material, the EOT of the layers are small, and thereby minimally affect the overall EOT of the gate stack of the memory cell 300. The trapping layers 332, 334 may be deposited by CVD, PECVD, ALD or other similar techniques. Examples of materials that may be deposited to form the trapping layers 332, 334 include silicon-nitride (Si₃N₄, K=7), silicon oxy-nitride (SiON, K=7), silicon-rich nitride (SRN, K=10-12), and aluminum nitride (AlN, K=10). Only a thin layer of the trapping layers 332, 334 is needed, and may be as thin as 3.2 nm or less.

The charge blocking layer 14 may be formed by oxide material or have the ONO configuration. Alternatively, as shown by a charge-blocking layer 414 in FIG. 4, a high K dielectric material may be utilized in place of the oxide material to reduce the overall EOT of the gate stack. Examples of high K materials that can be used for the charge-blocking layer 414 include alumina (Al₂O₃, K≈9), hafnium silicon oxynitride (HfSiON, K≈17), lanthanum aluminum oxide (LaAlO₃, K≈27.5) and other high K dielectrics such as lanthanide based oxides, oxy-silicates and aluminates. FIG. 4 also includes the trapping layers 332, 334 made of high K materials. Therefore, the EOT of the entire gate stack may be reduced by using high K materials for both the charge-blocking layer 414 and the trapping layers 332, 334.

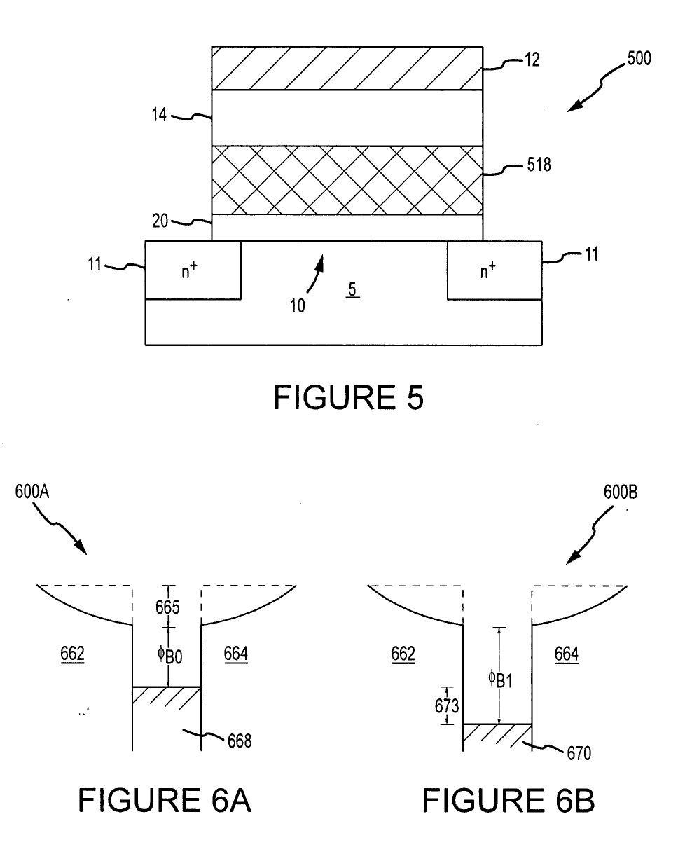

In another embodiment of a memory cell 500 shown in FIG. 5, a floating gate 518 may be modified by doping the floating gate 518 with P⁺ material to further reduce reverse-tunneling and charge leakage. The prior art polysilicon floating gate 18 as shown in FIG. 1 is conventionally N⁺ doped. Therefore, overlapped regions of the floating gate 18 to the N⁺ source/drain regions 11 provide almost a 1.0 eV lower energy barrier, thereby causing an increase in reverse tunneling of stored charges to source/drain regions 11, and creating enhanced leakage paths particularly in these overlapped regions. The floating gate 518 may instead be doped with P⁺ material, such as boron, to eliminate the preferred leakage path associated with the overlap of the floating gate with the source/drain regions 11. The floating gate structure 518 may be formed by a boron-doped poly deposition, and then flush remove boron-carrying species for additional layer of the stack. Rapid thermal annealing (RTA) the completed stack may be utilized to activate the boron during the fabrication process.

FIGS. 6A and 6B further illustrate the benefit of P⁺ doping the floating gate 518, and includes band diagrams 600A, 600B that compare band energy levels of the prior art N⁺ doped polysilicon floating gate 18 (shown as FIG. 6A) to the P⁺ doped polysilicon floating gate 518 (shown as FIG. 6B). A floating gate energy band 668 represents the conventionally N⁺ doped floating gate 18. The tunnel layer 20 (conventionally of a tunnel oxide material) adjacent to the floating gate 18 is shown to have an energy barrier 662 at the interface and an energy barrier 664 due to the other interface with the charge blocking oxide layer 14. The energy barriers 662, 664 exhibit a lowering of the barrier 665 (from an ideal energy level shown as the dotted line) typically due to the grainy interfaces of the oxide layers and the floating gate 18, thus creating high local fields and charge leakage as previously explained. Consequently, the magnitude of the work function Φ_{B0} (which is due to the tunneling barrier for electrical conduction across the oxide-silicon interface) between the N⁺ floating gate 18 and the tunnel oxide 20 interface is reduced. By doping the floating gate 518 with P⁺ material, the floating gate energy band 670 is lower, thus increasing the work function whose magnitude is represented by Φ_{B1}. Consequently, the energy barrier levels at the floating gate 518 interfaces are greater due to Φ_{B1}>Φ_{B0}. By increasing the energy barriers the formation of leakage paths in the overlapping regions of the source/drain 11 are reduced.

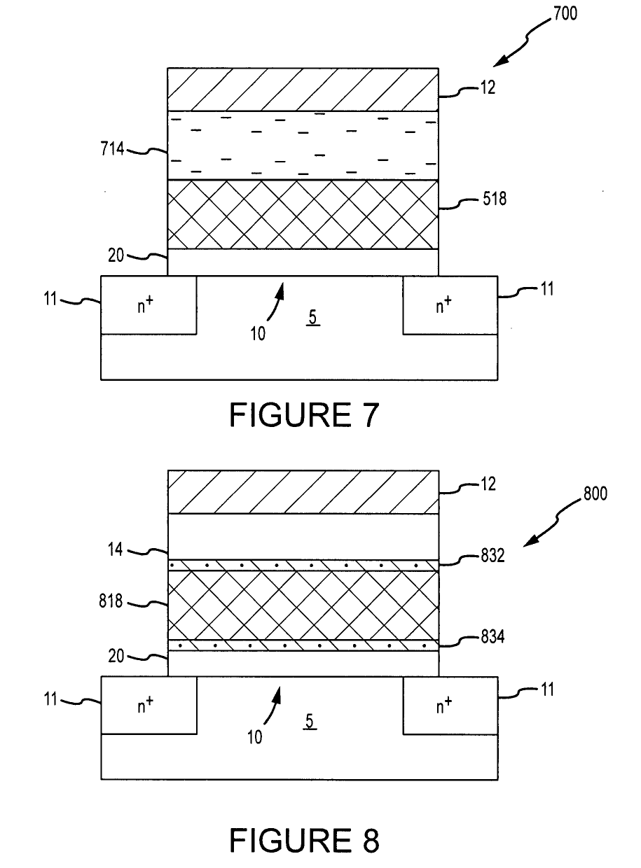

Similar to the memory cell 400 in FIG. 4, the EOT of the gate stack shown in FIG. 5 may be further reduced by including a charge blocking layer 714 that is formed with high K dielectric materials, as shown in a memory cell 700 of FIG. 7. As in FIG. 4, the same types of materials that include alumina (Al₂O₃, K≈9), hafnium silicon oxynitride (HfSiON, K≈17), or lanthanum aluminum oxide (LaAlO₃, K≈27.5) may be utilized to form the charge blocking layer 714. The combination of the P⁺ floating gate 518 and the high K charge blocking layer 714 allows simultaneously lower EOTs that reduce the programming voltage requirement and provide flexibility in scaling, and improved charge retention, particularly in the overlapping regions with the source/drain 11.

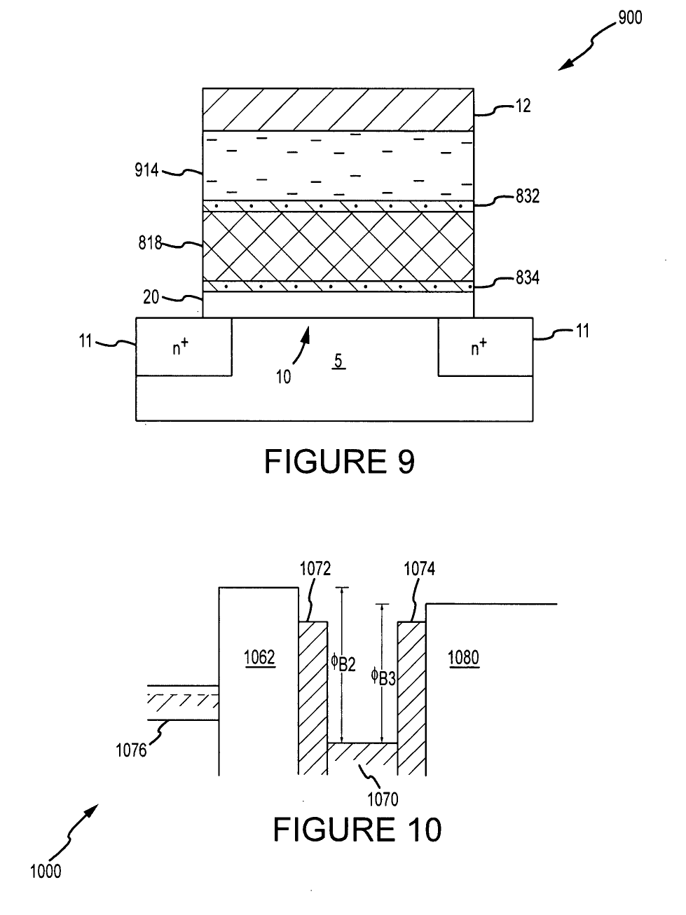

FIG. 8 shows a memory cell 800 that combines the features of a P⁺ floating gate 818 between trapping layers 832, 834. The trapping layer 832, 834 provide the floating gate 818 with smoother interfaces with both the tunnel layer 20 and the charge blocking layer 14. The thin layers 832, 834 may be formed with the same high K materials described to form the layers 332, 334 of FIG. 3. Additionally, the floating gate 818 is P⁺ doped to minimize leakage paths in the overlapped source/drain regions 11. The P⁺ floating gate 818 and layers 832, 834 further isolate stored charges and improve charge retention. FIG. 9 additionally includes a charge blocking layer 914 that may be formed with the same types of high K material as the charge blocking layers 414, 714 of FIGS. 4 and 7 such that the EOT of the gate stack may be reduced. Therefore, the programming voltage may be reduced and voltage scalability is achieved while charge retention is maintained.

The memory cell 900 may be fabricated using standard processing for Flash technology through higher temperature steps such as isolation, well implants and higher temperature drive-ins, and high threshold voltage device fabrication steps outside the array regions. In one example for forming the memory cell 900, the first trapping layer 834 may be formed by CVD deposition of a trapping layer dielectric, such as Si₃N₄ or SiON or SRN. Undoped polysilicon may be formed within the same chamber (at a first temperature range, for example 600-850° C.), followed by boron-doped poly deposition. Boron-carrying species are flush removed, and deposition of Si₃N₄, SiON or SRN in a second chamber may be conducted at a reduced temperature (such as 550-750° C.) compared to the first deposition. Rapid thermal annealing for boron activation may be utilized on the gate stack, followed by CVD deposition of another thin layer 832 of Si₃N₄ or SiON or SRN on the top surface of the boron-doped floating gate. Subsequently, high K material, such as alumina or HfSiON or LaAlO₃, may be deposited by CVD or ALD sputtering techniques to form the charge blocking layer 914. Finally, a gate polysilicon is deposited to form the control gate 12, followed by standard processes for gate definition, S/D processing, activation, glass-passivation and reflow, and back-end of the line processing.

FIG. 10 is an energy band diagram 1000 that shows the energy bands for the memory cell 900. The energy band diagram includes energy bands 1062, 1070, 1072, 1074, 1076, and 1080 for the tunnel oxide 20, the P+ floating gate 818, the thin layers 832, 834, the N⁺ source/drain regions 11, and the charge blocking layer 914, respectively. The combination of the thin layers 832, 834 and the P⁺ floating gate 818 increases the magnitude of the work function at the gate-dielectric interfaces. The smoothing effect at the silicon-insulator interfaces due to the layers 832, 834 is represented by the energy bands 1072, 1074, and shows an increased barrier level by the energy bands 1062, 1080. The P⁺ floating gate 818, represented by the energy band 1070, further increases the magnitude of the work function in the same manner as described previously. Therefore, the magnitude of the work function for the tunnel-oxide 20 interface is Φ_{B2}>>Φ_{B0}, and the magnitude of the work function for the charge blocking layer 14 interface is Φ_{B3}>>Φ_{B0}, where Φ_{B0} represents the magnitude of the work function of the interfaces in the prior art memory cell 100 of FIG. 1 and FIG. 6A.

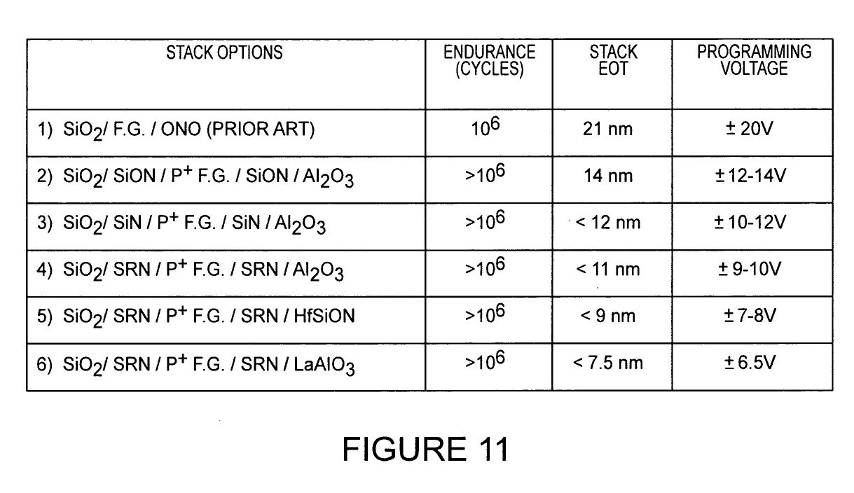

FIG. 11 is a table that includes a selection of gate stack options, wherein different combinations of high K materials yield different EOT values and change the programming voltage requirement for the particular device. As previously described, voltage scalability may be achieved by varying the high K materials used to form the layers 832, 834 and the charge blocking layers 914, and thus changing the overall EOT of the device. The samples in this set all use a tunnel oxide material for the tunnel layer 20 and have a P⁺ doped floating gate 818 between thin trapping layers 832, 834. However, by varying the type of high K material used to form the trapping layers 832, 834 and the charge blocking layer 914, in accordance to the previously described embodiments, different programming voltage requirements may be achieved. For example, gate stack option 2 includes an SiO₂—SiON—P⁺ floating gate-SiON—Al₂O₃ configuration having an EOT of 14 nm compared to gate stack option 1 which lists the prior art configuration as having an EOT of 21 nm. Consequently, gate stack option 2 requires a programming voltage ranging between 12-14V, which is 6-8V less than the prior art gate stack option 1. By changing the high K materials, the programming voltage may be further reduced as shown by a gate stack option 6, where the trapping layers 832, 834 are replaced by SRN and the charge blocking layer 914 is replaced by LaAlO₃ to yield a programming voltage requirement as low as 6.5V. It will be appreciated that not all the combinations or types of high K materials are shown in the table of FIG. 11. Other materials that have not been described, in other combinations, using still higher K values, may also be utilized to achieve even a lower EOT, and thus the programming voltage, for flexible scalability. Such materials include, but are not limited to, other lanthanide-based oxides, transition metal-based oxides, oxynitrides, silicates, aluminates, mixed oxides, and composites and laminates with high K values.

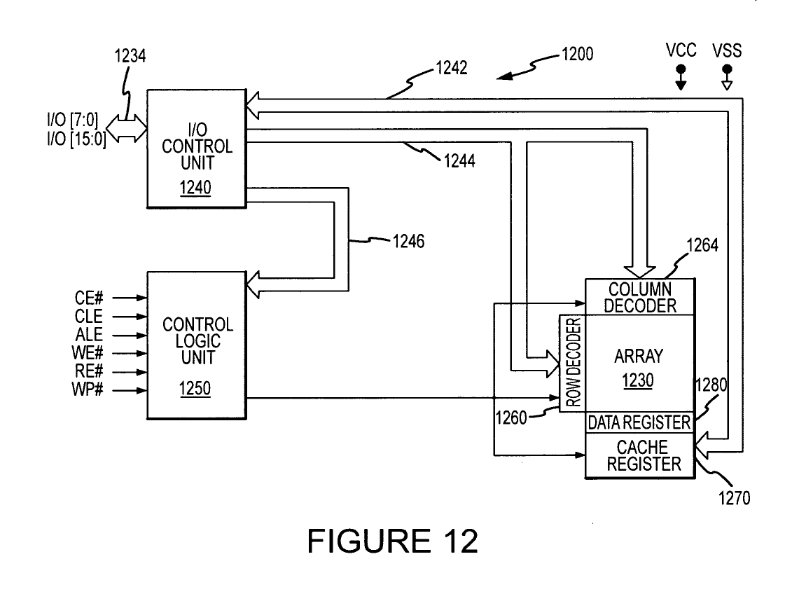

A flash memory device 1200 that includes an array of flash memory cells 1230 is shown in FIG. 12. For example, each memory cell in the array 1230 may be configured according to one of the stack options 2-6 in FIG. 11 such that the total EOT of each cell is less than the EOT of the prior art memory cell. Most command signals, address signals and the write data signals are applied to the memory device 1200 as sets of sequential input/output (“I/O”) signals transmitted through an I/O bus 1234. Similarly, read data signals are output from the flash memory device 1200 through the I/O bus 1234. The I/O bus is connected to an I/O control unit 1240 that routes the signals between the I/O bus 1234 and an internal data bus 1242, an internal address bus 1244, and an internal command bus 1246. The flash memory device 1200 also includes a control logic unit 1250 that receives a number of control signals either externally or through the command bus 1246 to control the operation of the memory device 1200. The address bus 1244 applies row address signals to a row decoder 1260 and column address signals to a column decoder 1264. The row decoder 1260 asserts word select lines corresponding to the decoded row address signals. Similarly, the column decoder 1264 enables write data signals to be applied to bit lines for columns corresponding to the column address signals and allow read data signals to be coupled from bit lines for columns corresponding to the column address signals.

In response to the memory commands decoded by the control logic unit 1250, the flash memory cells in the array 1230 are erased, programmed, or read. The memory array 1230 is programmed on a row-by-row or page-by-page basis. After the row address signals have been applied to the address bus 1244, the I/O control unit 1240 routes write data signals to a cache register 1270. The write data signals are stored in the cache register 1270 in successive sets each having a size corresponding to the width of the I/O bus 1234. The cache register 1270 sequentially stores the sets of write data signals for an entire row or page of flash memory cells in the array 1230. All of the write data signals are then used to program a row or page of memory cells in the array 1230 selected by the row address coupled through the address bus 1244. In a similar manner, during a read operation, data signals from a row or page of memory cells selected by the row address coupled through the address bus 1244 are stored in a data register 1280. Sets of data signals corresponding in size to the width of the I/O bus 1234 are then sequentially transferred through the I/O control unit 1240 from the data register 1280 to the I/O bus 1234.

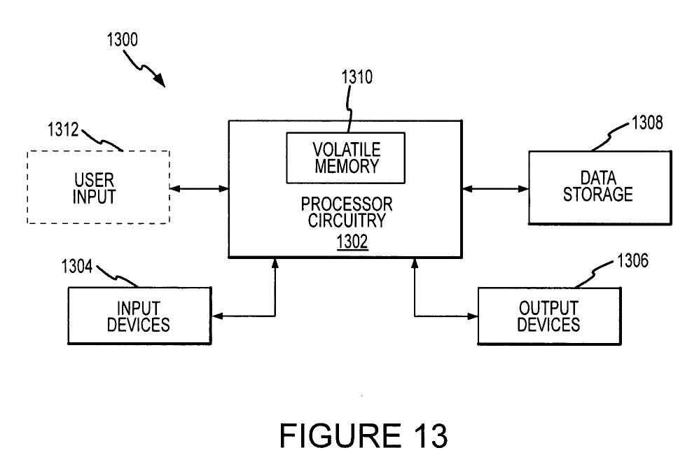

FIG. 13 is a block diagram of an embodiment of a processor-based system 1300 that includes the memory device 1200 of FIG. 12. Conventionally, the processor circuitry 1302 is coupled through address, data, and control buses to a volatile memory device 1310 to provide for writing data to and reading data from the volatile memory device 1310. The processor circuitry 1302 includes circuitry for performing various processing functions, such as executing specific software to perform specific calculations or tasks. In addition, the processor-based system 1300 may include one or more input devices 1304, such as a keyboard or a mouse, coupled to the processor circuitry 1302 to allow an operator to interface with the processor-based system 1300. Typically, the processor-based system 1300 may also include one or more output devices 1306 coupled to the processor circuitry 1302, such as output devices typically including a printer and a video terminal. One or more data storage devices 1308 are also typically coupled to the processor-based circuitry 1302 to store data or retrieve data from external storage media (not shown). Examples of typical storage devices 1308 include hard and floppy disks, tape cassettes, compact disk read-only (“CD-ROMs”) and compact disk read-write (“CD-RW”) memories, and digital video disks (“DVDs”). Data storage devices 1308 may also include non-volatile memory devices to store data that is to be retained even when power is not supplied to the processor-based system 1300 or the data storage devices 1308, such as a flash memory device according to some other examples of the invention. The non-volatile memory devices may include memory arrays with memory cells structured to have high K dielectric materials and P⁺ doped floating gates, such as one or more of the embodiments described above.

FIG. 13 may alternatively be a block diagram of a user accessory device 1312, such as a cell phone, digital camera or other hand-held device, coupled to the processor 1302. The processor 1302 may be a microprocessor, digital signal processor, or part of a central processing unit that communicates with the user input 1312 over a bus. The processor 1302 may additionally have non-volatile memory such as flash memory, or rely on the data storage device 1308.

From the foregoing it will be appreciated that, although specific embodiments of the invention have been described herein for purposes of illustration, various modifications may be made without deviating from the spirit and scope of the invention. Accordingly, the invention is not limited except as by the appended claims.

What is claimed is:

1. A memory cell, comprising:
a channel region extending between first and second diffusion regions formed in a substrate;
a tunnel dielectric material disposed over the channel region;
a storage medium disposed over the tunnel dielectric material, the storage medium configured to store electrical charge;
a first interface material disposed at the interface between the tunnel dielectric material and the storage medium;
a charge blocking material disposed over the storage medium;
a second interface material disposed at the interface between the charge blocking material and the storage medium; and
a control gate disposed over the charge blocking material.

2. The memory cell of claim 1 wherein the charge blocking material comprises a high K dielectric material.

3. The memory cell of claim 2 wherein the high K dielectric material comprises a material from at least one of lanthanide-based oxides, transition metal-based oxides, oxynitrides, silicates, aluminates, mixed oxides, composites and laminates.

4. The memory cell of claim 3 wherein the high K dielectric material includes at least one of alumina, hafnium silicon oxynitride, and lanthanum aluminum oxide.

5. The memory cell of claim 2 wherein the storage medium comprises a P⁺ doped polysilicon material.

6. The memory cell of claim 2 wherein the first and second interface materials comprise a material of at least one of silicon-nitride, silicon oxy-nitride, silicon-rich nitride and aluminum nitride.

7. A memory cell, comprising:
a channel region extending between first and second diffusion regions formed in a substrate, the first and second diffusion regions being doped with a first material having a first polarity;
a tunnel dielectric material adjacent the channel region;
a storage medium adjacent the tunnel dielectric material, the storage medium being doped with a second material having a second polarity that is opposite of the first polarity, the storage medium configured to store electrical charge;
a charge blocking material adjacent the storage medium; and
a control gate adjacent the charge blocking material.

8. The memory cell of claim 7 wherein the first material comprises N⁺ doped silicon substrate and the second material comprises P⁺ doped polysilicon material.

9. The memory cell of claim 8 wherein the polysilicon material is doped with boron.

10. The memory cell of claim 7 wherein the charge blocking material comprises a high K dielectric material.

11. A memory device, comprising:
an array of memory cells, each of the memory cells in the array comprising:
a source region and a drain region formed in a substrate adjacent opposite ends of a channel region;
a tunnel oxide material formed over the channel region;
a storage medium formed over the tunnel oxide material, the storage medium configurable to store and discharge an electrical charge responsive to an electric field;
a first interface material formed between the tunnel oxide material and the storage medium, the first interface material structured to be resistant to a local electric field at the tunnel oxide and storage medium interface responsive to the electric field;
a charge blocking material formed over the storage medium;
a second interface material formed between the charge blocking material and the storage medium, the second interface material structured to be resistant to a local electric field at the charge blocking material and storage medium interface responsive to the electric field; and
a control gate formed over the charge blocking medium, the control gate operable to receive a bias voltage that generates the electric field.

12. The memory device of claim 11 wherein the charge blocking material comprises a high K dielectric material.

13. The memory device of claim 12 wherein the high K dielectric material comprises a material from at least one of lanthanide-based oxides, transition metal-based oxides, oxynitrides, silicates, aluminates, mixed oxides, composites and laminates.

14. The memory device of claim 13 wherein the high K dielectric material includes at least one of alumina, hafnium silicon oxynitride, and lanthanum aluminum oxide.

15. The memory device of claim 11 wherein the storage medium comprises a P⁺ doped polysilicon material.

16. The memory device of claim 11 wherein the first and second interface materials comprise a layer of at least one of silicon-nitride, silicon oxy-nitride, silicon-rich nitride and aluminum nitride.

17. A processor-based system comprising:
processor circuitry; and
at least one memory device having an array of memory cells, each of the memory cells comprising:
a gate stack having a scalable effective oxide thickness, the gate stack comprising:
a tunnel dielectric material formed over a channel region disposed between source/drain regions;
a storage medium formed over the tunnel dielectric material, the storage medium configurable to store electrical charge;
a first interface material formed between the tunnel dielectric material and the storage medium, the first interface material structured to smooth the interface between the storage medium and the tunnel dielectric material;
a charge blocking material formed over the storage medium;
a second interface material formed between the charge blocking material and the storage medium, the second interface material structured to smooth the interface between the charge blocking material and the storage medium; and
a control gate formed over the charge blocking material.

18. The processor-based system of claim 17 wherein the charge blocking material comprises a high K dielectric material.

19. The processor-based system of claim 17 wherein the floating gate comprises a P⁺ doped polysilicon material.

20. The processor-based system of claim 17 wherein the at least one memory device comprises a flash memory device located in a data storage device.

21. The processor-based system of claim 17 wherein the processor circuitry is coupled to a CMOS imager device.

22. The processor-based system of claim 17 wherein the first and second interface materials comprise a material of at least one of silicon-nitride, silicon oxy-nitride, silicon-rich nitride and aluminum nitride.

23. A method of forming a memory cell, comprising:
forming first and second diffusion regions in a substrate, the first and second diffusion regions adjacent opposite ends of a channel region in the substrate;
forming a tunnel dielectric material over the channel region with a first dielectric material;
forming a charge storage material over the tunnel dielectric material;
forming a charge blocking material over the charge storage material with a second dielectric material;
forming a first interface material between the charge storage material and the tunnel dielectric material and a second interface material between the charge storage material and the charge blocking material, the first and second interface materials being a high K dielectric material; and
forming a control gate over the charge blocking material.

24. The method of claim 23 wherein forming the charge storage material comprising P⁺ doping the charge storage material with boron.

25. The method of claim 23 wherein forming the first and second interface materials comprise depositing a material of at least one of silicon-nitride, silicon oxy-nitride, silicon-rich nitride and aluminum nitride.

26. The method of claim 21 wherein the high K dielectric material comprises a material from at least one of lanthanide-based oxides, transition metal-based oxides, oxynitrides, silicates, aluminates, mixed oxides, composites and laminates.

27. The method of claim 26 wherein the high K dielectric material comprises at least one of alumina, hafnium silicon oxynitride and lanthanum aluminum oxide.

28. A method of operating a memory cell, comprising:
tunneling an electrical charge either to or from a storage medium of the memory cell responsive to an applied programming voltage;
smoothing the interface surrounding the storage medium with a first high K dielectric material; and
doping the storage medium with a material having a polarity opposite to the polarity of at least one material surrounding the storage medium.

29. The method of claim 28 wherein the storage medium is doped with boron.

30. The method of claim 28 wherein smoothing the interface surrounding the storage medium with the first high K dielectric material comprises surrounding the storage medium with a material of at least one of silicon-nitride, silicon oxy-nitride, silicon-rich nitride and aluminum nitride.

31. The method of claim 28 further comprising forming a charge blocking material adjacent to the storage medium, wherein the charge blocking material comprises a second high K material.

32. The method of claim 31 wherein the applied programming voltage is scalable by changing the type of first high K dielectric material and the type of second high K dielectric material.

33. The method of claim 32 wherein the second high K dielectric material comprises at least one of alumina, hafnium silicon oxynitride and lanthanum aluminum oxide.
